(19) United States
(12) Patent Application Publication
(10) Pub. No.: US 2024/0429117 A1
(43) Pub. Date: Dec. 26, 2024

(54) DIELECTRIC MATERIAL AND A MOLD COMPOUND WITH DIFFERENT DIELECTRIC CONSTANTS COUPLED TO A DIE THAT INCLUDES INTEGRATED CIRCUITRY

(71) Applicant: Intel Corporation, Santa Clara, CA (US)

(72) Inventors: Harshit DHAKAD, Bangalore (IN); Georgios C. DOGIAMIS, Chandler, AZ (US); Georg SEIDEMANN, Landshut (DE); Bernd WAIDHAS, Pettendorf (DE); Thomas WAGNER, Regelsbach (DE); Manisha DUTTA, Munich (DE); Michael LANGENBUCH, Munich (DE)

(21) Appl. No.: 18/338,176

(22) Filed: Jun. 20, 2023

(51) Int. Cl. H01L 23/31; H01L 21/56; H01L 23/00; H01L 23/42; H01L 23/498; H01L 23/552

(52) U.S. Cl. CPC H01L 23/3128; H01L 21/56; H01L 23/3135; H01L 23/42; H01L 23/49822; H01L 23/552; H01L 24/16; H01L 24/32; H01L 24/73; H01L 2224/16225; H01L 2224/32225; H01L 2224/73204

(57) ABSTRACT

Embodiments herein relate to systems, apparatuses, techniques or processes for reducing the capacitance of a package that includes a die by at least partially surrounding the die within a mold compound and a dielectric material with different dielectric constants. Other embodiments may be described and/or claimed.

### FIELD

Embodiments of the present disclosure generally relate to the field of package assemblies, and in particular package assemblies that include dies that are at least partially encapsulated within a mold compound.

### BACKGROUND

During the manufacturing of computing systems, packages that contain dies that include integrated circuitry are physically and electrically coupled with other system components, such as interposers, substrates, or motherboards. During the transportation and/or handling of the packages, electrical charges may build up within the packages due to a high capacitance of the package with respect to a ground plane. The capacitance of the package is a major determinant for the charged-device model (CDM) of the package. The CDM is a model for characterizing the susceptibility of a packaged integrated circuit (IC) to damage from electrostatic discharge.

When the package is physically and electrically coupled to the other components on assembly lines, short duration, high amperage electrostatic discharge, or spark, may occur between the package and the conductive component of the assembly lines. For example, the time duration of the CDM electrostatic discharge may be few nano seconds (ns) with rise times in the range of 100-300 pico seconds (ps). Part of the CDM current pulse could be rising as fast as 20-30 ps and during that time the resulting electric current flow may be several amperes at 250 volts, depending on the capacitance of the package.

Even though this electrostatic discharge is for a short period of time, the large voltage drop resulting from the discharge may cause damage to devices within the packaged IC. Such damage may include, for example, damage to transistor structures such as gate oxides, interlayer dielectrics, and the like within dies of the package. This resulting damage may result in increased yield loss, and as a result increase overall manufacturing cost.

As a result, dies, or chips, within a package often include electrostatic discharge (ESD) protection devices, which may be referred to as ESD protection structures, within the dies or chips proximate to integrated circuitry, which may be also referred to as electrical circuitry, in order to mitigate damage from high voltage electrostatic discharges during assembly.

### BRIEF DESCRIPTION OF THE DRAWINGS

FIG. 1 illustrates a legacy package with a die that includes an integrated circuit with ESD protection devices, a redistribution layer, and a ball grid array (BGA) on the redistribution layer.

FIGS. 2A-2D include example illustrations and circuitry for characterizing a CDM for a package, and a graph of an example CDM waveform during testing.

FIGS. 3A-31 illustrate various cross-section side views and cross-section top-down views of dielectric material and a mold compound with different dielectric constants coupled to a die, in accordance with various embodiments.

FIGS. 4A-4F illustrate cross-section side views of stages in a manufacturing process for creating a package that includes dielectric material and a mold compound with different dielectric constants coupled to a die, in accordance with various embodiments.

FIG. 5 illustrates an example of a process for creating a package that includes dielectric material and a mold compound with different dielectric constants coupled to a die, in accordance with various embodiments.

FIG. 6 schematically illustrates a computing device, in accordance with embodiments.

### DETAILED DESCRIPTION

Embodiments of the present disclosure may generally relate to systems, apparatus, and/or processes directed to reducing the capacitance of a package and as a result reducing the peak CDM current of the package. In embodiments, the package may include a die that includes one or more ICs within the die, where the die is at least partially surrounded by a combination of a mold compound and a dielectric material. In embodiments, the mold compound may be referred to as a molding. In embodiments, the mold compound and the dielectric material have different dielectric constants. For example, the mold compound may have a higher dielectric constant than the dielectric material. In embodiments, the mold compound may partially surround the die and the dielectric material may be on the mold compound. In other embodiments, portions of the mold compound and/or the dielectric material may both be proximate to the die, and/or may be in direct physical contact with the die.

In embodiments, the presence of the dielectric material proximate to the die may reduce the capacitance of the package, and as a result may result in a reduced size of the electrostatic discharge protection device within the die. The electrostatic discharge protection device may be used in order to prevent high current discharges, and the associated subsequent device damage, associated with ESD when the package is electrically and/or physically coupled with another component during system manufacture.

By enabling a reduced size electrostatic discharge protection device within the die, this may reduce the high-capacity loading of signals routed within the die, thus improving die and package performance. Also, electrical leakage may be reduced, hence reducing overall power requirements of the integrated circuit, and the size of the die may also be smaller. Performance of high-speed interfaces may be significantly improved by reducing capacitive loading by reducing the size of ESD protection devices because the peak CDM currents will be reduced. In addition, there may be a reduction in noise coupling from surroundings as we now lower package capacitance. In embodiments, a material of the mold compound may include a dielectric material.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

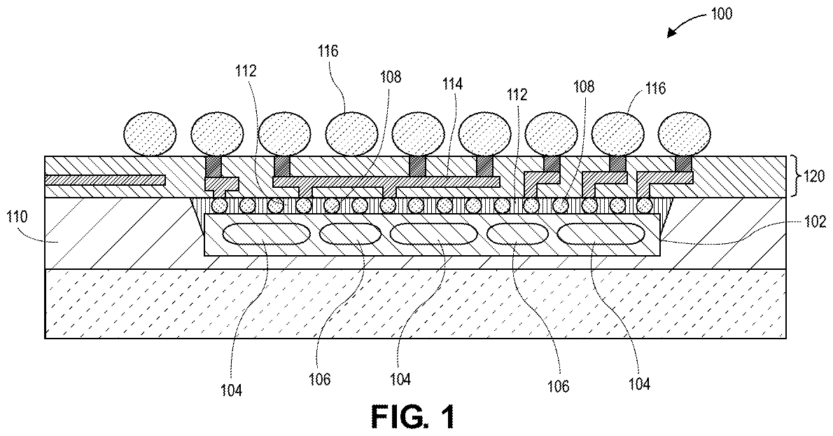

FIG. 1 illustrates a legacy package with a die that includes an integrated circuit with ESD protection devices, a redistribution layer, and a ball grid array (BGA) on the redistribution layer. Package 100 shows a cross-section side view of a legacy package that includes a die 102. The die 102 includes integrated circuitry 104, which may include, but not be limited to, transistors, capacitors, and/or other active or passive circuitry. The integrated circuitry 104 may be distributed throughout portions of the die 102. The integrated circuitry 104 may include metallic and/or other structures that may contribute capacitance for the package 100.

The die 102 may also include ESD protection devices 106. In embodiments, ESD protection devices 106 may include, but are not limited to, single diodes, dual diodes, self-protected output drivers for digital I/O, and/or rail clamps. Electrical connections 108, which may include solder bumps and/or conductive pads, are on a side of the die 102 and are electrically coupled with the integrated circuitry 104. Although FIG. 1 shows three different areas of integrated circuitry 104 and two areas for ESD protection devices 106, in implementations, the integrated circuitry 104 and the ESD protection devices 106 may appear anywhere within the die 102.

The die 102 may be embedded or partially embedded within a mold compound 110. A redistribution layer (RDL) 120 may be on the die 102 and electrically coupled with the die 102 using electrical connections 108. The RDL 120 may include various electrical routings 114 that electrically couple the electrical connections 108 on a first side of the RDL 120 to a ball grid array (BGA) 116 on a second side of the RDL 120 opposite the first side. In implementations, an underfill 112 may be placed between the die 102 and the RDL 120, and between the electrical connections 108.

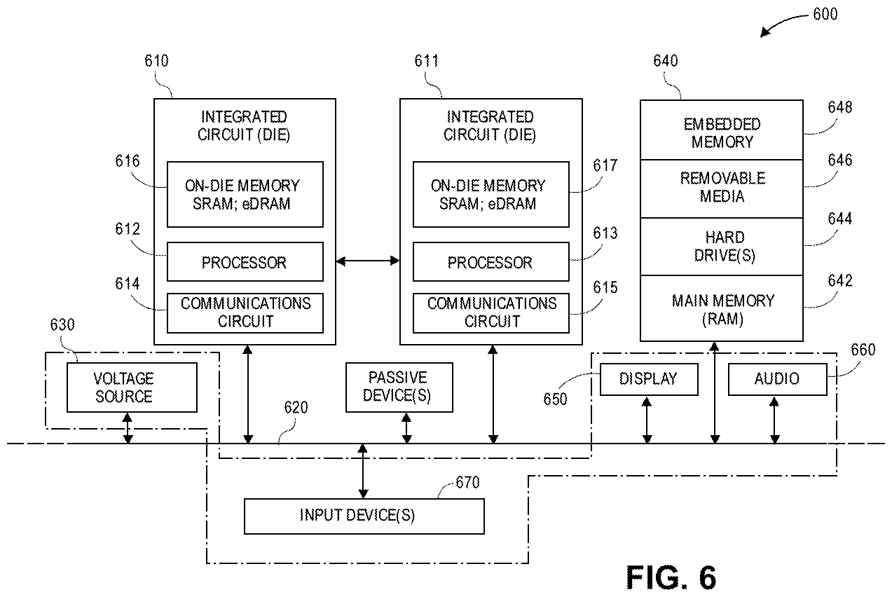

In implementations, the ESD protection devices 106 may be used to protect the integrated circuitry 104 of the die 102 from ESD events that may occur when the package 100 is assembled with another component, for example a motherboard (not shown), during manufacturing of a computer system. The computer system may be similar to computer system 600 of FIG. 6. The structure of package 100, including the die 102, the integrated circuitry 104, and the mold compound 110, create a capacitance for the package 100. In particular, each package 100 may have a capacitance characteristic or model that may be referred to as a CDM, discussed further below.

When a package 100 is being transported, for example, along rollers on its way to an insertion machine, a static electricity charge may build up in the package 100 depending on the CDM of the package 100. When one of the BGA 116 touches a conductive component, for example, a metal pin of a motherboard (not shown) during insertion onto the motherboard or any other conductive component, any electrostatic charge built up within the package 100 will be immediately discharged into the conductive component.

This ESD event may be a very fast event that may result in a large voltage drop for the package 100 at a very high current rate. The overall time of the event may be on the order of 1-2 ns or less, and may be as short as 20 to 300 ps. The current generated may be very high, in some packages the current may range between 5-6 amps with a 250 volt charging. For packages that are used in automotive computing systems, the amperage might be as high as 10 to 15 amps at a 500V charging.

With the high current discharge, there may come a large voltage drop that may cause damage to the integrated circuitry 104. For example, this may include damage to gate oxides, sources and/or drains of metal oxide semiconductor (MOS) devices, parasitic bipolar, junctions, and/or interlayer dielectrics. Note that when the package 100 is coupled with a motherboard (not shown), there may be board-level protection for electrostatic discharge, and when the motherboard (not shown) is inserted into a system (not shown), the system may have system-level ESD protection, including shielding and system chassis for discharge.

In legacy implementations, the ESD protection devices 106 within the die 102 are made large enough so that the CDM, based upon the capacitance of the package 100, meets target standards to be able to handle a threshold current during an ESD event during manufacture. This threshold current may be expressed as a breakdown voltage of the package 100. If the CDM target requirements are not met, yield losses for the package 100 may exceed 3% to 4%, and in some implementations may exceed 20%.

A substantial amount of the capacitance of the package 100 is contributed by the mold compound 110 surrounding the die 102. The mold compound 110 may be included to provide structural stability and/or thermal conductivity properties for the die 102. In implementations, a typical dielectric constant for the mold compound 110 may be greater than or equal to 4. In these implementations, as the size of the package 100 increases, the size and complexity of the ESD protection devices 106 may also need to be increased. However, an increase in the size of the ESD protection devices 106 may cause tradeoffs.

For example, an increased size or number of ESD protection devices 106 may add additional capacitance or may load high-speed interfaces, and affect the frequency of input/output (I/O) that may be achieved through the electrical connections 108 on the die 102. For example, high speed I/O that may be transmitting at 50 or 100 gigabits per second within the integrated circuitry 104 or the electrical connections 108 may be subject to increased noise. In addition, large ESD protection devices 106 may also increase the amount of electrical leakage within the die 102, and may increase the overall size of the die 102.

Thus, in embodiments, the size of ESD protection devices 106 may be reduced, without having to reduce the CDM requirement for the package 100, by reducing the amount of mold compound 110 with a higher dielectric constant that is proximate to the die 102.

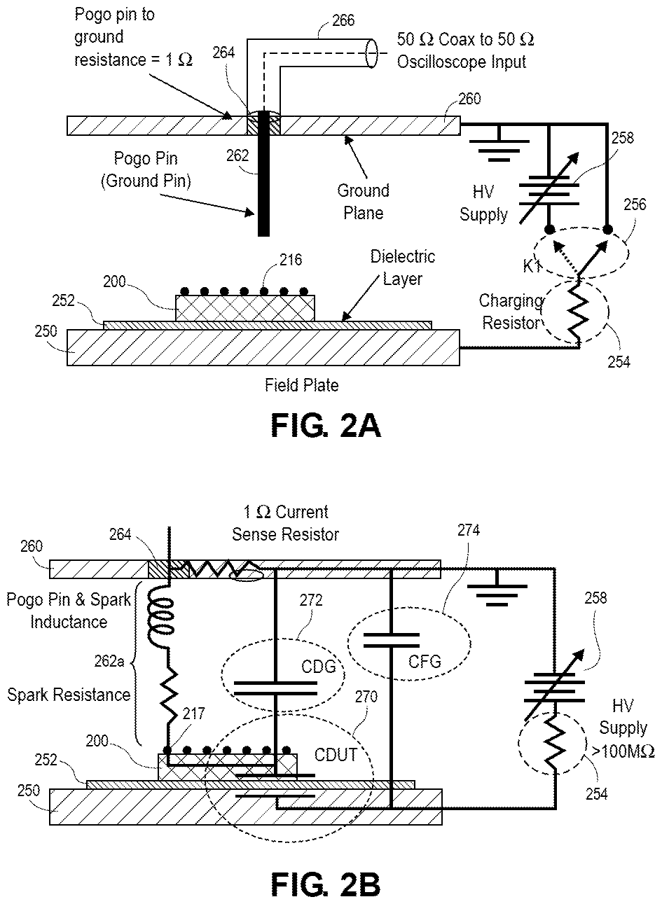

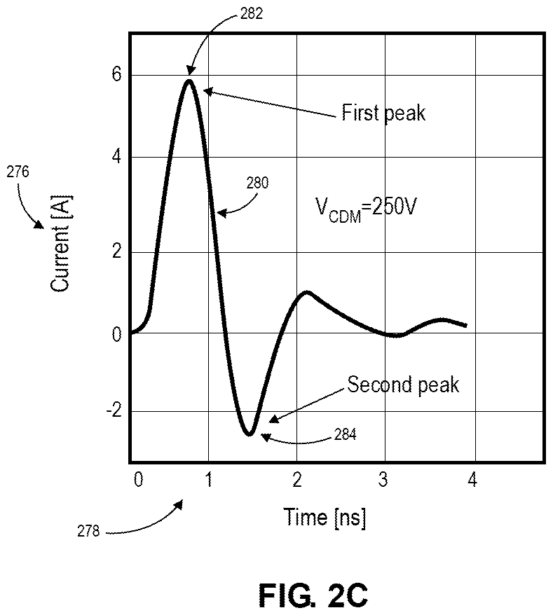

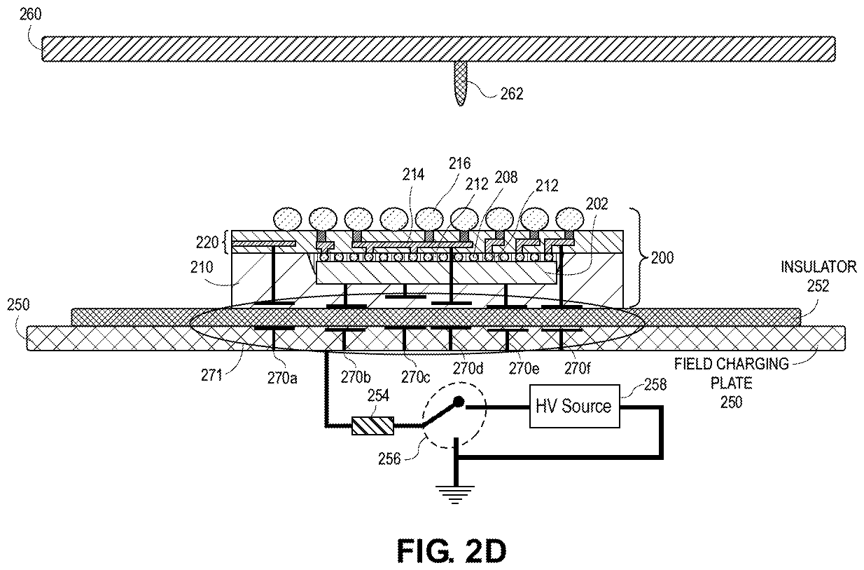

FIGS. 2A-2D include example illustrations and circuitry for characterizing a CDM for a package, and a graph of an example CDM waveform during testing. FIG. 2A shows a diagram of a system used to measure the CDM of a package 200, which may be similar to package 100 of FIG. 1. The package 200 may be on a dielectric layer 252 that is on a field plate 250. In implementations, the field plate 250 may be electrically coupled to a charging resistor 254 that may be switched using switch 256 with a high-voltage supply 258. In implementations, either may be coupled with a ground plane 260. The ground plane 260 is electrically connected to a pogo pin 262, through a one ohm resistor 264, the resistance and inductance of the spark and the pogo pin 262 may be coupled using a 50 ohm coaxial cable 266 to a 50 ohm input of an oscilloscope (not shown).

During operation, the package 200 will be charged to a high-voltage, for example, to 250 volts. Once the package 200 is fully charged, the pogo pin 262 will be connected to a solder ball of BGA 216, which may be similar to BGA 116 of FIG. 1, and the package 200 will be discharged through the solder ball of BGA 216. The resulting discharge will then be measured. This process may be repeated for each of the solder balls on the package 200, and values of each of the tests will be combined to determine the CDM for the package 200.

FIG. 2B shows an equivalent circuit diagram of the CDM test environment shown in FIG. 2A. FIG. 2B shows a field plate 250, dielectric layer 252 on the field plate 250, and package 200 on the dielectric layer 252. Sub-diagram 262a is the equivalent diagram of the spark resistance, inductance, and resistance of the pogo pin 262 of FIG. 2A, which is electrically coupled with solder ball 217, which may be similar to the solder ball of BGA 216 of FIG. 2A. The sub-diagram 262a shows as electrically coupled with the ground plane 260 and the one ohm resistor 264.

The capacitance shown at CDUT 270 is the capacitance of the package 200, which may also be referred to as the device under test (DUT). The capacitance shown at CDG 272 is shown as the capacitance between the package 200 and the ground plane 260. The capacitance shown at CFG 274 is the capacitance between the field plate 250 and the ground plane 260. As shown in FIG. 2B, all of the charge held in the capacitance shown at CDUT 270 is discharged through the spark shown in sub-diagram 262a and one ohm resistor 264 to the ground plane 260. During testing, this may be done for both polarities, positive and negative.

FIG. 2C shows an arbitrary discharge waveform 280, which may be referred to as a CDM stress waveform, of y-axis 276 showing electrical current in amps plotted against x-axis 278 showing time in nanoseconds. As shown, the package 200 of FIG. 2B has been charged to 250 volts. The resulting waveform 280 is an oscillating waveform that exponentially decreases in amplitude. For example, waveform 280 shows a first peak 282 at about 6 amps and a second peak 284 at-2.2 amps that ranges between 1-2 ns in time. It should be noted that each of the solder balls 217 of package 200 of FIG. 2B may have a different waveform, even though for each iteration the charge placed on the package 200 will be the same.

FIG. 2C shows that the maximum current discharge is very high, and also that the capacitance of the package 200, or CDUT 270, is directly proportional to the dielectric constant of the medium, for example mold compound 110 of FIG. 1, between the dielectric layer 252 of FIG. 2B and the integrated circuitry within the package 200, which may be similar to integrated circuitry 104 of die 102 of package 100 of FIG. 1. This is due in part to the relative permittivity/dielectric constant of the mold compound 110 as having a value of 4 or greater. The capacitance of a parallel plate capacitance is given by the formula

C=ε₀εᵣA/d

where A is the area of the plate, d is the separation distance between the plates, ε₀ is permittivity of free space, and εᵣ is relative permittivity, or the dielectric constant k, of the dielectric material between the plates.

FIG. 2D shows another diagram of package 200 that is on dielectric layer 252 that is on the field plate 250. The package 200 includes mold compound 210, die 202, electrical connections 208, underfill 212, RDL 220, electrical routings 214, and BGA 216, which may be similar to mold compound 110, die 102, electrical connections 108, underfill 112, RDL 120, electrical routings 214, and BGA 116 of FIG. 1. FIG. 2D may be similar to FIG. 2A. Region 271 includes individual sub-regions 270a, 270b, 270c, 270d, 270e, 270f, each with individual capacitances that may be combined to identify the capacitance CDUT 270 of FIG. 2B of the package 200.

As a result, the CDM peak current depends on the package 200 capacitance CDUT 270, which also determines the amount of charge that may be stored in the package 200 that includes ICs (not shown). The capacitance CDUT 270 is directly proportional to the dielectric constant of the mold compound 210, or any other substance, that may be between the dielectric layer 252 and the RDL 220. In legacy implementations, the mold compound 210 has a relative permittivity or dielectric constant of greater than 4. Due to this, the capacitance generated may be very high, in the range of several pico-farads to several tens of pico-farads. Accordingly, as shown in FIG. 2C, CDM peak currents may be very high, in the range of several amperes.

Thus, in legacy implementations, due to the high capacitance CDUT 270 of the package 200, the charge stored in the package 200 may be large, and the peak CDM current during ESD may be very high. To guard against high voltage drops from ESD during package insertion, the size of ESD protective devices, such as ESD protective device 106 of FIG. 1, is increased. This results in higher capacitive loading on the signals within the package 200, a larger size of the package 200, and increased power leakage and higher power requirements for the package 200. These results may be due in part to the ESD protective device 106. These legacy implementations with high capacitive loading may be very disadvantageous for high speed interfaces or low-power integrated circuits within the package 200.

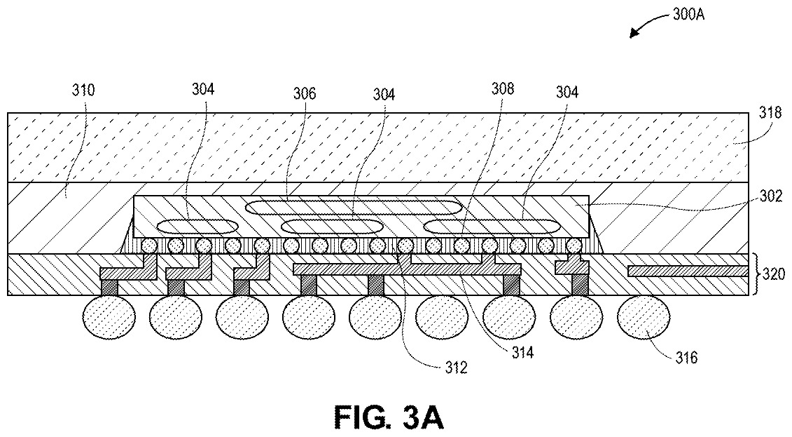

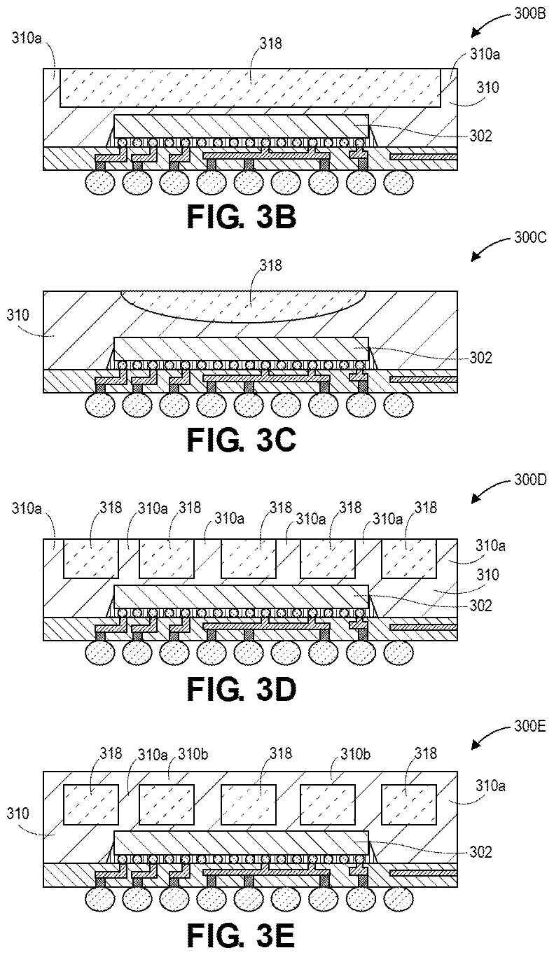

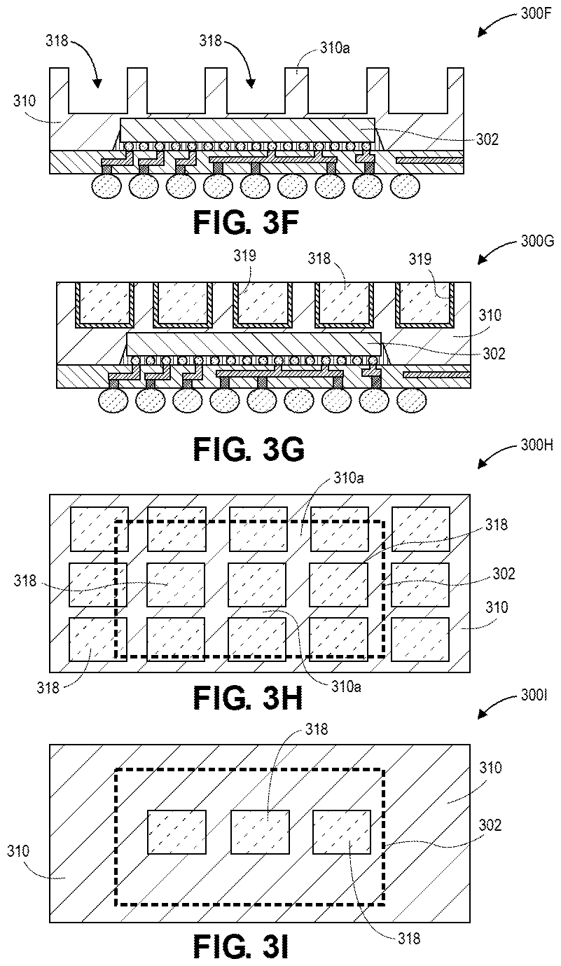

FIGS. 3A-3I illustrate various cross-section side views and cross-section top-down views of dielectric material and a mold compound with different dielectric constants coupled to a die, in accordance with various embodiments. In FIGS. 3A-3I, various embodiments of a low to ultra-low εᵣ (or k) layer, which may be in the form of a dielectric layer and may be patterned onto or coated onto a high-k mold compound layer, are presented to reduce the capacitance of a package, such as capacitance CDUT 270 of FIG. 2D.

FIG. 3A shows cross-section side view of package 300A, which may be similar to package 100 of FIG. 1. Package 300A includes die 302, integrated circuitry 304, ESD protection device 306, electrical connections 308, underfill 312, RDL 320, electrical routings 314, BGA 316, and mold compound 310, which may be similar to die 102, integrated circuitry 104, ESD protection device 106, electrical connections 108, underfill 112, RDL 120, electrical routings 114, BGA 116, and mold compound 110 of FIG. 1.

Embodiments include a dielectric material 318 that is on the mold compound 310. In embodiments, the dielectric material 318 may have a value of a dielectric constant that is less than the value of the dielectric constant of the mold compound 310. In embodiments, the mold compound 310 may have a value of a dielectric constant of around 4 or greater, and the dielectric material 318 may have a value of a dielectric constant of around 2 or less. In embodiments, the dielectric material 318 may be considered a low-k, or an ultra-low-k dielectric layer. In embodiments, a height of the mold compound 310 may be reduced as compared to the height of the mold compound 110 of FIG. 1, such that the height of the mold compound 310 in addition to the height of the dielectric material 318 will cause the package 300A to have a similar height to the package 100 of FIG. 1.

In embodiments, the dielectric material 318 may be a layer having an arbitrary or varying thickness. In embodiments, the dielectric material 318 may have a thickness that is non-uniform. In embodiments, the dielectric material 318 may consist of multiple dielectric materials, one or more of which may have a lower dielectric constant. In embodiments, the dielectric material 318 may be a layer that is substantially perpendicular to a surface of the die 302. In other embodiments, the dielectric material 318 may extend to or extend beyond at least one side of the die 302, where the at least one side of the die is perpendicular or substantially perpendicular to the surface of the die 302.

In embodiments, the ESD protection device 306 within the die 302 may be smaller than the ESD protective device 106 within the die 102 of FIG. 1, because the CDM of the package 300A will be less than the CDM of the package 100 of FIG. 1. This is due to the existence of the lower-k dielectric material 318 reducing the overall capacitance of the package 300A. As a result, in embodiments, charge storage of the package 300A may be less than the size of the volume of the package 100 of FIG. 1, due to the existence of the lower-k dielectric material 318.

FIG. 3B shows a cross-section side view of package 300B, which may be similar to package 300A of FIG. 3A, where the dielectric material 318 is inserted into a portion of the mold compound 310. In embodiments, portions of the mold compound 310a may extend along the sides of the dielectric material 318. In embodiments, the dielectric material 318 may be proximate to the die 302 in order to reduce the overall capacitance, and hence reduce a peak CDM discharge current of the package 300B. In embodiments, some portions of the mold compound 310a may be left in place in order to provide additional structural integrity and/or thermal properties for the package 300B. In embodiments, the mold compound 310 may have a higher degree of structural integrity than the dielectric material 318.

In addition, the dielectric material 318 may have lower thermal conductive properties then the mold compound 310, and therefore be less able to route heat away from the die 302 during operation. As a result, a minimum thickness of the mold compound 310 may be required between the die 302 and the dielectric material 318 in order to adequately dissipate heat from the die 302. In some embodiments (not shown), a heat spreader may be placed within the mold compound 310 and/or within the dielectric material 318 to route heat away from the die 302.

FIG. 3C shows a cross-section side view of package 300C, which may be similar to package 300B of FIG. 3B, where the dielectric material 318 is formed within a cavity in the mold compound 310. However, unlike FIG. 3B, the dielectric material 318 may not have any straight edges or planar sides within the mold compound 310. In embodiments, this structure may allow the dielectric material 318 to be closer to portions of the die 302 that may include higher metallization and therefore reduce the capacitance with respect to that portion of the die 302. As a result, the volume and shape of the dielectric material 318 may be chosen in a way to tailor a capacitive value for the package 300C that may be unique to the die 302.

FIG. 3D shows a cross-section side view of package 300D, which may be similar to package 300B of FIG. 3B, where the dielectric material 318 has been broken into individual sections and inserted within mold compound 310. In embodiments, each of the individual sections may be separated by a portion of the mold compound 310a, which may be used to provide rigidity to the package 300D. In embodiments, each of the individual sections of dielectric material 318 may be placed over areas of the die 302 that may include metal structures (not shown), which may be similar to integrated circuitry 104 of FIG. 1. In embodiments, part of the dielectric material 318 may also extend beyond the edge of the die 302. In embodiments, the dielectric material 318 may be filled inside of cavities that are created within the mold compound 310 during manufacture of the package 300D.

FIG. 3E shows a cross-section side view of package 300E, which may be similar to package 300D of FIG. 3D, where the dielectric material 318 may be inserted within the mold compound 310. In embodiments, a first section of mold compound 310a may be between the sections of the dielectric material 318, and a second section of mold compound 310b may be above the dielectric material 318. In embodiments, the second section of mold compound 310b may provide additional rigidity to the package 300E. In embodiments, this additional rigidity may allow additional force to be applied on the top side of the package 300E during insertion, and/or reduce warping of the package 300E during insertion or operation. In embodiments, the second section of mold compound 310b may also provide thermal conductivity to provide an enhanced thermal path between the die 302, the first section of mold compound 310a and to the second section of mold compound 310b to the top of the package 300E.

FIG. 3F shows a cross-section side view of package 300F, which may be similar to package 300D of FIG. 3D, where the dielectric material 318 may include air. FIG. 3G shows a cross-section side view of package 300G, which may be similar to package 300D of FIG. 3D, where a thermally conductive paste 319 may be inserted between the dielectric material 318 and the mold compound 310. In embodiments, the thermally conductive paste 319 may be any other type of thermally conductive material and may be placed on the package 300F after the package is assembled on a printed circuit board assembly.

FIG. 3H shows a cross-section top-down view of package 300H, which may be similar to package 300D of FIG. 3D. The individual sections of dielectric material 318 may be formed within the mold compound 310, and may be separated by portions of mold compound 310a. The die 302 may be below the individual sections of dielectric material 318, and may extend beyond the footprint of the die 302.

FIG. 3I shows a cross-section top-down view of package 300I, which may be similar to package 300D of FIG. 3D, where individual sections of dielectric material 318 may be formed over only a few portions of the die 302. In embodiments, these individual sections of dielectric material 318 may be positioned over places within the die 302 that have a higher contribution to the capacitance of the package 300I, with the mold compound 310 to provide package rigidity and/or thermal properties.

It should be appreciated that FIGS. 3A-3I are examples of embodiments but do not limit the application of the dielectric material 318 within or on the mold compound 310. Other embodiments may include mixes and matches of characteristics of dielectric material 318, mold compound 310, and/or other materials or cavities that may be inserted within the package to facilitate a reduction in capacitance for a package.

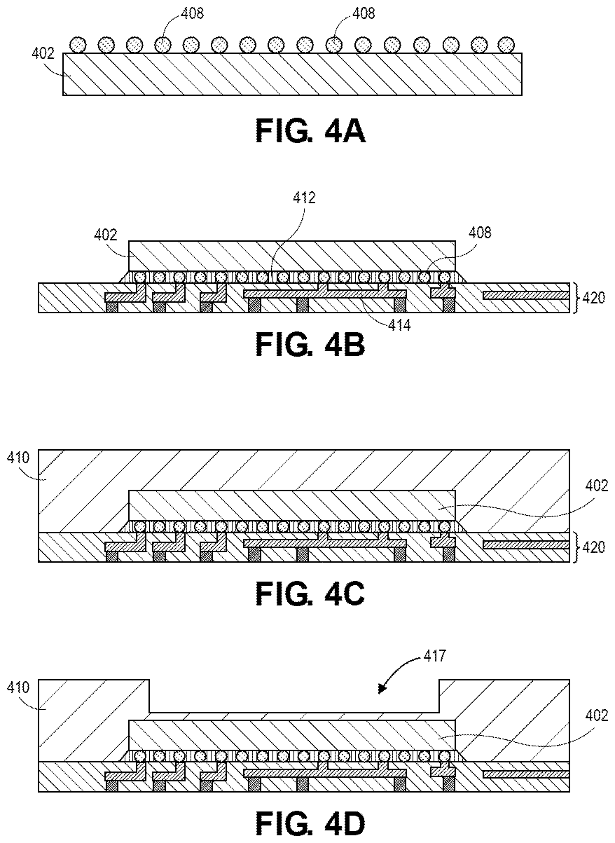

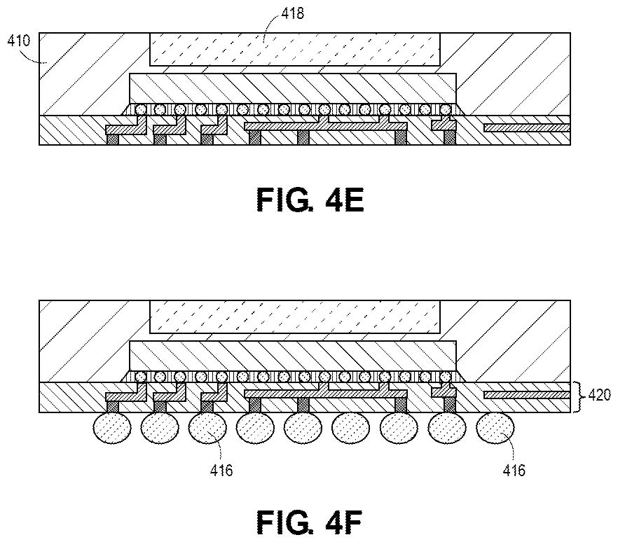

FIGS. 4A-4F illustrate cross-section side views of stages in a manufacturing process for creating a package that includes dielectric material and a mold compound with different dielectric constants coupled to a die, in accordance with various embodiments. FIG. 4A illustrates a stage in the manufacturing process where a die 402 is provided and electrical connections 408 may be electrically and/or physically coupled with the die 402. Die 402 and electrical connections 408 may be similar to die 102 and electrical connections 108 of FIG. 1. In embodiments, the electrical connections 108 may be implemented as solder bumps, such as micro bumps, or may be copper or other metallic connections.

FIG. 4B illustrates a stage in the manufacturing process where the die 402 and the electrical connections 408 may be applied to a redistribution layer 420, which may be similar to RDL 120 of FIG. 1. In embodiments, the redistribution layer 420 may include electrical routings 414 that may electrically couple with one or more of the electrical connections 408. In embodiments, an underfill 412 may be placed between the die 402 and the redistribution layer 420 in order to provide a secure mechanical coupling between the die 402 and the redistribution layer 420.

FIG. 4C illustrates a stage in the manufacturing process where a mold compound 410 is formed over the die 402 and at least part of the redistribution layer 420. In embodiments, the mold compound 410 may be similar to mold compound 110 of FIG. 1. In embodiments, the mold compound 410 may be flowed over and/or compressed onto the die 402 and the redistribution layer 420.

FIG. 4D illustrates a stage in the manufacturing process where a cavity 417 may be formed within the mold compound 410. In embodiments, the cavity 417 may be made using an etch process or a drill or be directly stamped during the mold compound compression.

FIG. 4E illustrates a stage in the manufacturing process where a dielectric material 418, which may be similar to dielectric material 318 of FIGS. 3A-3E, may be inserted into the cavity 417 of FIG. 4D. In embodiments, the dielectric material 418 may be placed using spray coating, spin coating, dispensing, 3D printing, squeegee and stencil printing, and/or other deposition techniques. A curing step may be also applied in some embodiments.

FIG. 4F illustrates a stage in the manufacturing process where a BGA 416, which may be similar to BGA 116 of FIG. 1, may be coupled with the redistribution layer 420.

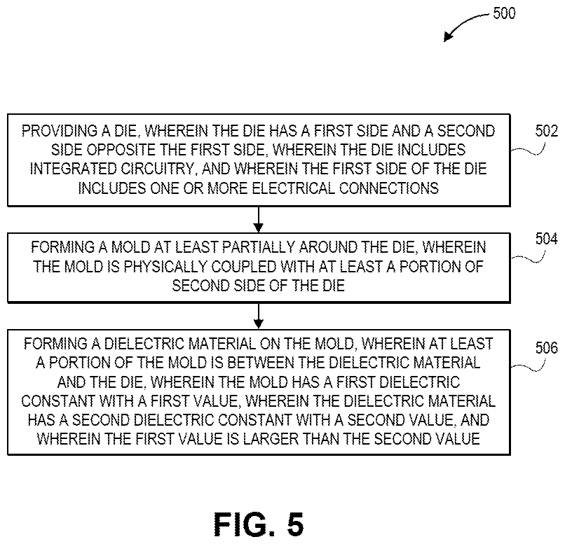

FIG. 5 illustrates an example of a process for creating a package that includes dielectric material and a mold compound with different dielectric constants coupled to a die, in accordance with various embodiments. Process 500 may be performed using the processes, techniques, apparatus, and/or systems described herein, and in particular with respect to FIGS. 3A-4F.

At block 502, the process may include providing a die, wherein the die has a first side and a second side opposite the first side, wherein the die includes integrated circuitry, and wherein the first side of the die includes one or more electrical connections. In embodiments, the die may be similar to die 302 of FIGS. 3A-31 or may be similar to die 402 of FIGS. 4A-4F. In embodiments, the electrical connections may be similar to electrical connections 308 of FIGS. 3A-31 or may be similar to electrical connections 408 of FIGS. 4A-4F.

At block 504, the process may further include forming a mold at least partially around the die, wherein the mold is physically coupled with at least a portion of a second side of the die.

In embodiments, the mold may be similar to mold compound 110 of FIG. 1, mold compound 310 of FIGS. 3A-31, or may be similar to mold compound 410 of FIGS. 4C-4F.

At block 506, the process may further include forming a dielectric material on the mold, wherein at least a portion of the mold is between the dielectric material and the die, wherein the mold has a first dielectric constant with a first value, wherein the dielectric material has a second dielectric constant with a second value, and wherein the first value is larger than the second value. In embodiments, the dielectric material may be similar to dielectric material 318 of FIGS. 3A-31, or may be similar to dielectric material 418 of FIGS. 4E-4F.

FIG. 6 is a schematic of a computer system 600, in accordance with an embodiment of the present invention. The computer system 600 (also referred to as the electronic system 600) as depicted can embody a dielectric material and a mold compound with different dielectric constants coupled to a die, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, a dielectric material and a mold compound with different dielectric constants coupled to a die, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having a dielectric material and a mold compound with different dielectric constants coupled to a die, according to any of the several disclosed embodiments and their equivalents, an electronic system, a computer system, one or more methods of fabricating an integrated circuit, and one or more methods of fabricating an electronic assembly that includes a package substrate having a dielectric material and a mold compound with different dielectric constants coupled to a die, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a dielectric material and a mold compound with different dielectric constants coupled to a die embodiments and their equivalents. A foundation substrate may be included, as represented by the dashed line of FIG. 6. Passive devices may also be included, as is also depicted in FIG. 6.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

The following paragraphs describe examples of various embodiments.

Example 1 is an apparatus comprising: a die; integrated circuitry within the die; a mold that at least partially surrounds the die, wherein the mold has a first dielectric constant; and a dielectric material on the mold, wherein the dielectric material has a second dielectric constant, wherein a first value of the second dielectric constant is smaller than a second value of the first dielectric constant.

Example 2 includes the apparatus of example 1, wherein at least a portion of the dielectric material is above the integrated circuitry, and wherein the dielectric material reduces a capacitance of the apparatus.

Example 3 includes the apparatus of examples 1 or 2, wherein the mold includes one or more cavities, and wherein the one or more cavities are at least partially filled with the dielectric material.

Example 4 includes the apparatus of examples 1, 2, or 3, wherein a portion of the dielectric material is directly physically coupled with the die.

Example 5 includes the apparatus of examples 1, 2, 3, or 4, wherein the dielectric material is a layer parallel to a surface of the die.

Example 6 includes the apparatus of example 5, wherein the dielectric material extends to at least one side of the die, wherein the at least one side of the die is perpendicular to the surface of the die.

Example 7 includes the apparatus of examples 1, 2, 3, 4, 5, or 6, wherein the dielectric material includes a selected one or more of: a modified poly imide (PI) resin, a liquid crystal polymer (LCP) resin, a covalent organic framework film (COF), a polytetrafluoroethylene (PTFE) polymer, or air.

Example 8 includes the apparatus of examples 1, 2, 3, 4, 5, 6, or 7, wherein a thickness of the dielectric material ranges from 10 micrometers to 10 millimeters, and a thickness of the mold ranges from 10 micrometers to 10 millimeters.

Example 9 includes the apparatus of examples 1, 2, 3, 4, 5, 6, 7, or 8, wherein a surface of the die includes one or more electrical contacts that are electrically coupled with the integrated circuitry.

Example 9.1 includes the apparatus of examples 1, 2, 3, 4, 5, 6, 7, 8, or 9, wherein a thickness of the dielectric material ranges from few micrometers to hundreds of micrometers, and a thickness of the mold ranges from few micrometers to hundreds of micrometers.

Example 9.2 includes the apparatus of example 9.1, wherein a width of the dielectric material is greater than a width of the mold.

Example 9.3 includes the apparatus of examples 1, 2, 3, 4, 5, 6, 7, 8, 9, 9.1 or 9.2, wherein the dielectric material is a low-k dielectric material.

Example 10 is a package comprising: a die that includes integrated circuitry; a first set of electrical connections at a first side of the die, wherein the first set of electrical connections is coupled with the integrated circuitry; a redistribution layer on the first side of the die, wherein a first side of the redistribution layer is electrically coupled with at least one of the first set of electrical connections at the first side of the die; a second set of electrical connections on a second side of the redistribution layer opposite the first side of the redistribution layer, wherein the second set of electrical connections are electrically coupled with the first set of electrical connections; a mold compound surrounding at least a portion of the die, wherein the mold compound is in direct physical contact with at least a portion of a second side of the die opposite the first side of the die; and a dielectric material coupled with the mold compound, wherein at least a portion of the mold compound is between the dielectric material and the die, wherein the mold compound has a first dielectric constant of a first value, wherein the dielectric material has a second dielectric constant of a second value, and wherein the first value is greater than the second value.

Example 11 includes the package of example 10, wherein the first value is greater than or equal to 3, and wherein the second value is less than or equal to 3.

Example 12 includes the package of examples 10 or 11, wherein the mold compound includes one or more cavities, wherein the one or more cavities are at least partially filled with the dielectric material, and wherein at least one of the one or more cavities are proximate to the integrated circuitry.

Example 13 includes the package of example 12, wherein the one or more cavities are surrounded by the mold compound.

Example 14 includes the package of examples 12 or 13, wherein the one or more cavities include thermally conductive paste.

Example 15 includes the package of examples 10, 11, 12, 13, or 14, wherein the dielectric material includes a selected one or more of: a modified poly imide (PI) resin, a liquid crystal polymer (LCP) resin, a covalent organic framework film (COF), a polytetrafluoroethylene (PTFE) polymer, or air, and wherein a thickness of the dielectric material ranges from 10 micrometers to 10 millimeters, and a thickness of the mold compound ranges from 10 micrometers to 10 millimeters.

Example 16 includes the package of examples 10, 11, 12, 13, 14, or 15, wherein the die includes electrostatic discharge protection structures.

Example 17 includes the package of examples 10, 11, 12, 13, 14, 15, or 16, wherein the first set of electrical connections or the second set of electrical connections include solder balls.

Example 18 is a method comprising: providing a die, wherein the die has a first side and a second side opposite the first side, wherein the die includes integrated circuitry, and wherein the first side of the die includes one or more electrical connections; forming a mold at least partially around the die, wherein the mold is physically coupled with at least a portion of the second side of the die; and forming a dielectric material on the mold, wherein at least a portion of the mold is between the dielectric material and the die, wherein the mold has a first dielectric constant with a first value, wherein the dielectric material has a second dielectric constant with a second value, and wherein the first value is larger than the second value.

Example 19 includes the method of example 18, wherein forming the mold further comprises forming the mold that includes one or more cavities within the mold, and wherein forming the dielectric material on the mold further comprises forming the dielectric material in at least a portion of the one or more cavities.

Example 20 includes the method of examples 18 or 19, wherein the dielectric material includes a selected one or more of: a modified poly imide (PI) resin, a liquid crystal polymer (LCP) resin, a covalent organic framework film (COF), a polytetrafluoroethylene (PTFE) polymer, or air.

What is claimed is:

1. An apparatus comprising:
a die;
integrated circuitry within the die;
a mold that at least partially surrounds the die, wherein the mold has a first dielectric constant; and
a dielectric material on the mold, wherein the dielectric material has a second dielectric constant, wherein a first value of the second dielectric constant is smaller than a second value of the first dielectric constant.

2. The apparatus of claim 1, wherein at least a portion of the dielectric material is above the integrated circuitry, and wherein the dielectric material reduces a capacitance of the apparatus.

3. The apparatus of claim 1, wherein the mold includes one or more cavities, and wherein the one or more cavities are at least partially filled with the dielectric material.

4. The apparatus of claim 1, wherein a portion of the dielectric material is directly physically coupled with the die.

5. The apparatus of claim 1, wherein the dielectric material is a layer parallel to a surface of the die.

6. The apparatus of claim 5, wherein the dielectric material extends to at least one side of the die, wherein the at least one side of the die is perpendicular to the surface of the die.

7. The apparatus of claim 1, wherein the dielectric material includes a selected one or more of: a modified poly imide (PI) resin, a liquid crystal polymer (LCP) resin, a covalent organic framework film (COF), a polytetrafluoroethylene (PTFE) polymer, or air.

8. The apparatus of claim 1, wherein a thickness of the dielectric material ranges from 10 micrometers to 10 millimeters, and a thickness of the mold ranges from 10 micrometers to 10 millimeters.

9. The apparatus of claim 1, wherein a surface of the die includes one or more electrical contacts that are electrically coupled with the integrated circuitry.

10. A package comprising:
a die that includes integrated circuitry;
a first set of electrical connections at a first side of the die, wherein the first set of electrical connections is coupled with the integrated circuitry;
a redistribution layer on the first side of the die, wherein a first side of the redistribution layer is electrically coupled with at least one of the first set of electrical connections at the first side of the die;
a second set of electrical connections on a second side of the redistribution layer opposite the first side of the redistribution layer, wherein the second set of electrical connections are electrically coupled with the first set of electrical connections;
a mold compound surrounding at least a portion of the die, wherein the mold compound is in direct physical contact with at least a portion of a second side of the die opposite the first side of the die; and
a dielectric material coupled with the mold compound, wherein at least a portion of the mold compound is between the dielectric material and the die, wherein the mold compound has a first dielectric constant of a first value, wherein the dielectric material has a second dielectric constant of a second value, and wherein the first value is greater than the second value.

11. The package of claim 10, wherein the first value is greater than or equal to 3, and wherein the second value is less than or equal to 3.

12. The package of claim 10, wherein the mold compound includes one or more cavities, wherein the one or more cavities are at least partially filled with the dielectric material, and wherein at least one of the one or more cavities are proximate to the integrated circuitry.

13. The package of claim 12, wherein the one or more cavities are surrounded by the mold compound.

14. The package of claim 12, wherein the one or more cavities include thermally conductive paste.

15. The package of claim 10, wherein the dielectric material includes a selected one or more of: a modified poly imide (PI) resin, a liquid crystal polymer (LCP) resin, a covalent organic framework film (COF), a polytetrafluoroethylene (PTFE) polymer, or air, and wherein a thickness of the dielectric material ranges from 10 micrometers to 10 millimeters, and a thickness of the mold compound ranges from 10 micrometers to 10 millimeters.

16. The package of claim 10, wherein the die includes electrostatic discharge protection structures.

17. The package of claim 10, wherein the first set of electrical connections or the second set of electrical connections include solder balls.

18. A method comprising:
providing a die, wherein the die has a first side and a second side opposite the first side, wherein the die includes integrated circuitry, and wherein the first side of the die includes one or more electrical connections;
forming a mold at least partially around the die, wherein the mold is physically coupled with at least a portion of the second side of the die; and
forming a dielectric material on the mold, wherein at least a portion of the mold is between the dielectric material and the die, wherein the mold has a first dielectric constant with a first value, wherein the dielectric material has a second dielectric constant with a second value, and wherein the first value is larger than the second value.

19. The method of claim 18, wherein forming the mold further comprises forming the mold that includes one or more cavities within the mold, and wherein forming the dielectric material on the mold further comprises forming the dielectric material in at least a portion of the one or more cavities.

20. The method of claim 18, wherein the dielectric material includes a selected one or more of: a modified poly imide (PI) resin, a liquid crystal polymer (LCP) resin, a covalent organic framework film (COF), a polytetrafluoroethylene (PTFE) polymer, or air.
